(19) United States
(12) Patent Application Publication
(10) Pub. No.: US 2009/0096070 A1
(43) Pub. Date: Apr. 16, 2009

(54) Semiconductor package and substrate for the same

(75) Inventors: Wen-Jeng Fan, Hsinchu (TW); Yi-Ling Liu, Hsinchu (TW)

Correspondence Address: Joe McKinney Muncy, PO Box 1364, Fairfax, VA, 22038-1364, US

(73) Assignee: POWERTECH TECHNOLOGY INC., Hsinchu (TW)

(21) Appl. No.: 12/068,623

(22) Filed: Feb. 8, 2008

(30) Foreign Application Priority Data
Oct. 10, 2007 (TW) 096147100

(51) Int. Cl. H01L 23/495; H05K 7/18

(52) U.S. Cl. 257/667; 361/813; 257/E23.043

(57) ABSTRACT

A semiconductor package is revealed with a special designed substrate. The substrate has a plurality of fingers, a dummy metal pattern, and at least a peripheral slot penetrating through the substrate. The dummy metal pattern is aligned to two opposing sides of the peripheral slot and is electrically isolated from the fingers. A chip is disposed on the substrate and is electrically connected to the fingers. An encapsulant is completely filled the peripheral slot. The peripheral slot can enhance the mold flow and eliminate the mold flash. The shape of the dummy metal pattern aligned to the peripheral slot is used to offer stiffening edges to prevent the substrate from warpage and from breakage at peripheries, to enhance the thermal stress resistance due to thermal cycles, and to avoid damages to the chip.

### FIELD OF THE INVENTION

The present invention relates to semiconductor devices, and more specifically to window-type semiconductor packages with peripheral windows and substrates for the same.

### BACKGROUND OF THE INVENTION

In the field of semiconductor packaging, a window-type semiconductor package has a substrate having one or more windows penetrating through the substrate to be a chip carrier so that the metal bonding wires or electrical connecting components can pass through the window to electrically connect the chip with the substrate. External terminals can be disposed on the substrate. Conventionally, one of the windows is disposed at the center of the substrate and is a narrow slot to expose a plurality of bonding pads of the chip. Normally, the chip has only several peripheral bonding pads which are much less than the ones at the center or even has no peripheral bonding pads. The others of the windows at the peripheries of the substrate are small in the shape of either rectangular or square. However, the rectangular or square small peripheral windows are prone to mold flash or void issues.

As shown in FIG. 1, a conventional window-type semiconductor package with small peripheral windows, primarily comprises a substrate 110, a chip 120, a plurality of electrical connecting components 130 such as bonding wires, and an encapsulant 140 such as EMC (Epoxy Molding Compound). The substrate 110 has a plurality fingers 111, a center slot 117, and a plurality of small peripheral windows 113 penetrating through the substrate 110. As shown in FIG. 2, a die-attaching area 114A is disposed on the top surface 114 of the substrate 110 for attaching the chip 110. A plurality of external pads 118 are disposed on the bottom surface 115 of the substrate 110. As shown in FIG. 1 and FIG. 2, the small peripheral windows 113 with rectangular or square shapes are formed at the sides of the substrate 110 to expose one or several peripheral bonding pads 122. Most of the electrical connecting components 130 pass through the center slot 117 to electrically connect the center bonding pads 121 of the chip 120 to the substrate 110. The rest of the electrical connecting components 130 pass through the small peripheral windows 113 to electrically connect the peripheral bonding pads 122 of the chip 120 to the substrate 110. Furthermore, a plurality of external terminals 150 such as solder balls are disposed on the external pads 118 as external electrical connections for the semiconductor package 100. The encapsulant 140 encapsulates the chip 120 and is formed in the center slot 117 and in the small peripheral windows 113 to encapsulate the electrical connecting components 130. Even the dimensions of the small peripheral windows 113 are either square or rectangular, they are much smaller than the one of the center slot 117. However, it is very difficult to manufacture many small peripheral windows 113 at the sides of the substrate 110, especially in controlling the shapes of the small peripheral windows 113, moreover, the manufacture cost of the substrate will be greatly increased. Furthermore, since it is not easy to fill the small peripheral windows 113 with the molding compound 140, therefore, mold flash will be an issue.

### SUMMARY OF THE INVENTION

The main purpose of the present invention is to provide a multi-window type semiconductor package and the substrate for the same. A peripheral slot disposed at the peripheries of the substrate by connecting a plurality of conventional small peripheral windows to facilitate mold flow and to eliminate mold flash. A dummy metal pattern is aligned to two opposing sides of the peripheral slot so as to reduce substrate warpage, to avoid substrate breakage, and to enhance thermal stress resistance of the peripheral slot under temperature cycles. Therefore, damages to the surface and to the sides of the chip can be eliminated.

According to the present invention, a semiconductor package primarily comprises a substrate, a chip, a plurality of electric connecting components, and an encapsulant. The substrate has a plurality of fingers, a dummy metal pattern, and at least a peripheral slot penetrating through the substrate where the dummy metal pattern is aligned to two opposing sides of the peripheral slot and is electrically isolated from the fingers. The chip with a plurality of bonding pads is disposed on the substrate. A plurality of electrical connecting components electrically connect the bonding pads of the chip to the fingers of the substrate. The encapsulant encapsulates the electrical connecting components and completely fills the peripheral slot. Furthermore, the substrate used for the semiconductor package is also revealed.

### DESCRIPTION OF THE DRAWINGS

FIG. 1 shows a cross-sectional view of a conventional window type BGA package.

FIG. 2 shows the top surface of a substrate of the conventional window type BGA package.

FIG. 3 shows the cross-sectional view of a semiconductor package according to the first embodiment of the present invention.

FIG. 4 shows the bottom surface of a substrate of the semiconductor package according to the first embodiment of the present invention.

FIG. 5 shows the top surface of the substrate of the semiconductor package according to the first embodiment of the present invention.

FIG. 6 shows the partially enlarged view of a peripheral slot of the substrate for the semiconductor package according to the first embodiment of the present invention.

FIG. 7 shows the partially enlarged view of the peripheral slot before formation on the substrate for the semiconductor package according to the first embodiment of the present invention.

FIG. 8 shows the partially enlarged view of the peripheral slot after die attachment on the substrate for the semiconductor package according to the first embodiment of the present invention.

FIG. 9 shows the partially enlarged view of another peripheral slot of a substrate for a semiconductor package according to the second embodiment of the present invention.

FIG. 10 shows the partially enlarged view of the peripheral slot before formation on a substrate for a semiconductor package according to the second embodiment of the present invention.

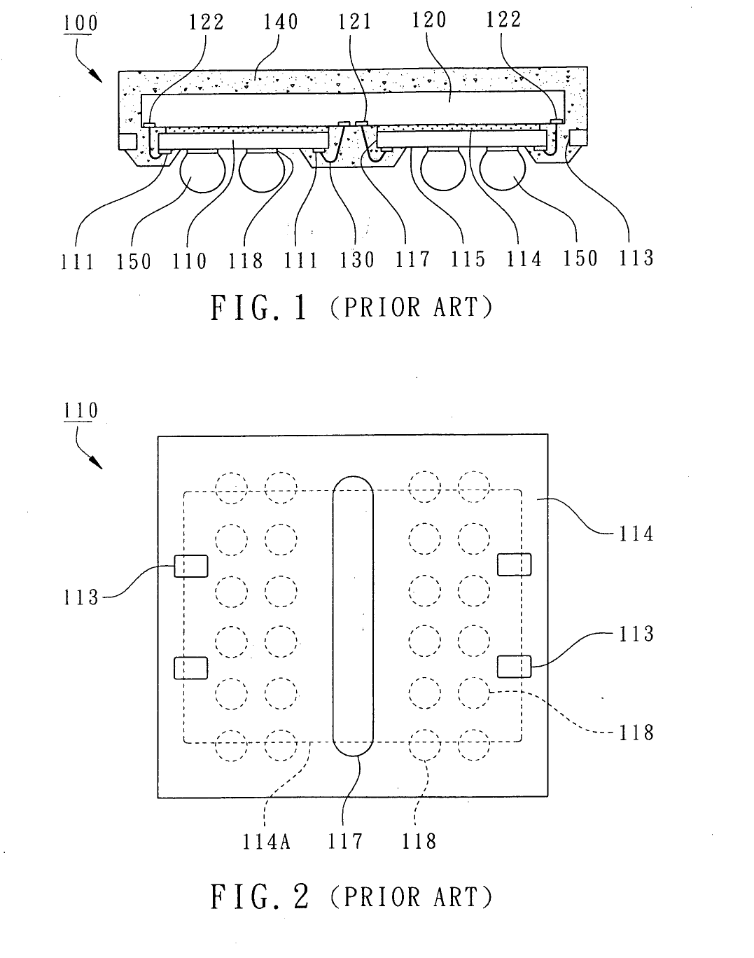

### DETAIL DESCRIPTION OF THE INVENTION

Please refer to the attached drawings, the present invention will be described by means of embodiments below.

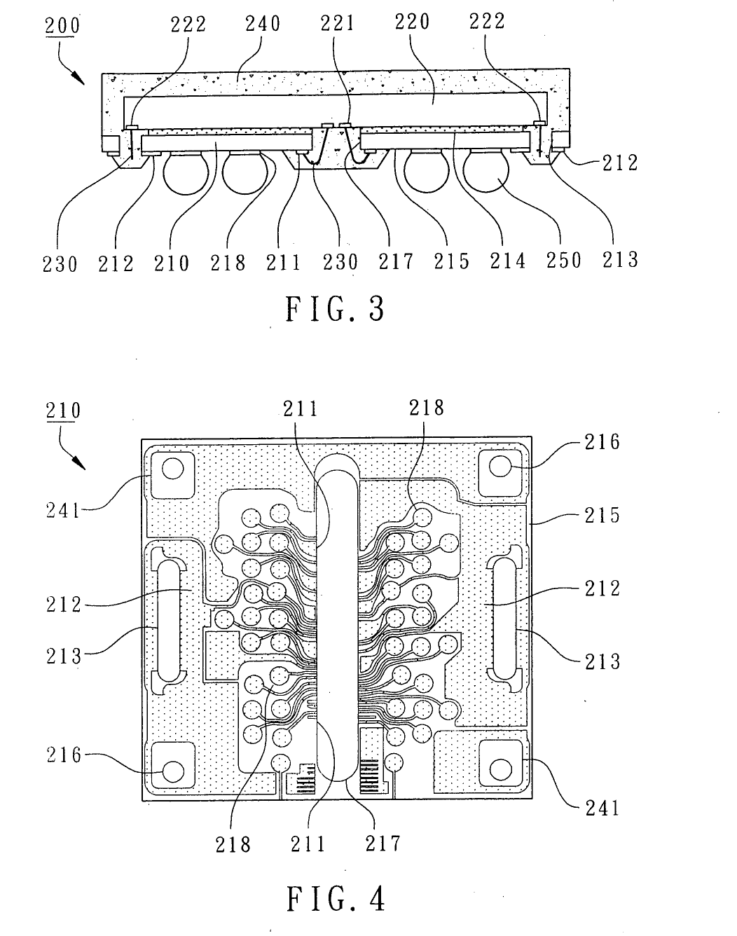

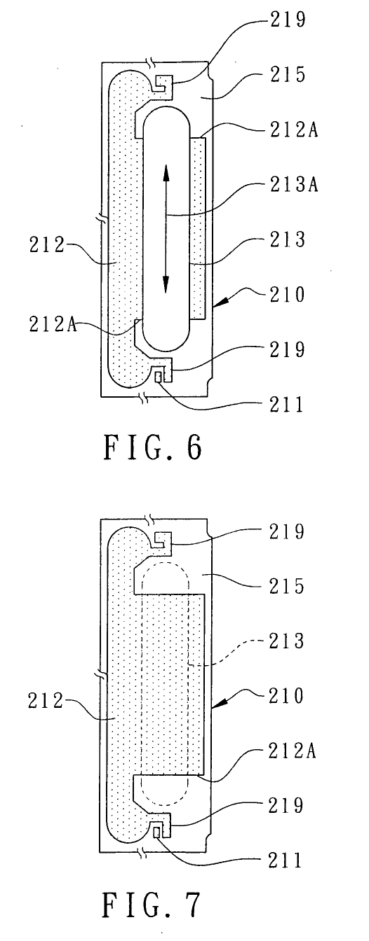

As shown in FIG. 3 and FIG. 4, a semiconductor package 200 primarily comprises a substrate 210, a chip 220, a plurality of electrical connecting components 230, and an encapsulant 240. The substrate 210 has a plurality of fingers 211, a dummy metal pattern 212, and at least a peripheral slot 213 penetrating through the substrate 210. The dummy metal pattern 212 has an extension aligned to two opposing sides of the peripheral slot 213 (as shown in FIG. 6) and is electrically isolated from the fingers 211 to avoid electric short. Therein, the two opposing sides are linear. Furthermore, the substrate 210 is a printed wiring board with single or multiple layers of circuit serves as a chip carrier. In the present embodiment, the substrate 210 further has a central slot 217 formed at the center of the substrate 210 for passing the electrical connecting components 230 and for filling the encapsulant 240. Preferably, the central slot 217 is parallel to the peripheral slot 213 for enhancing mold flow and for easy fabrication. In this embodiment, the peripheral slot 213 is shorter than the central slot 217 but with a width similar to the one of the central slot 217.

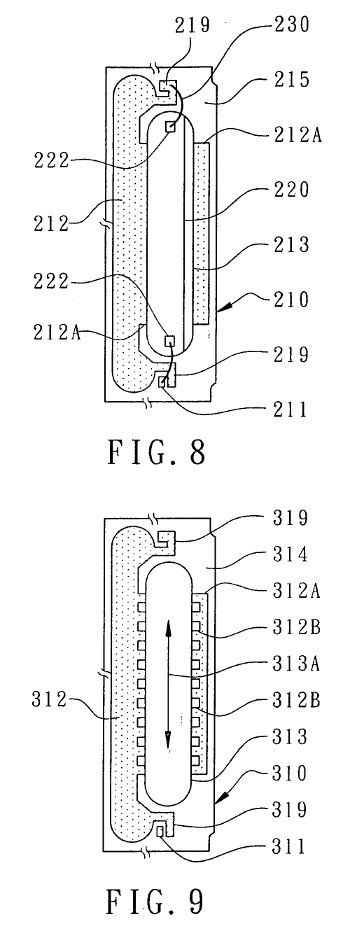

Accordingly, each peripheral slot 213 can replace a plurality of conventional small peripheral windows. As shown in FIG. 8, each peripheral slot 213 has two end openings each used as a small peripheral windows at the peripheries of the substrate 210 to expose one or several peripheral bonding pads 222 of the chip 220 aligned in the both ends of the peripheral slot 213. In this embodiment, a dummy passage including two opposing sides of each peripheral slot 213 connects two end openings where the dummy passage stands for the openings areas at the peripheries of the substrate 210 to expose one side of the chip 220, however, there is no peripheral bonding pads of the chip 220 exposed within the dummy passage except for the end openings of the peripheral slot 213. Through the peripheral slot 213, the complexity and the numbers of openings created on the substrate 210 can be reduced to facilitate mold flow and to eliminate mold flash. However, the strength at the peripheries of the substrate 210 is weakened.

Therefore, as shown in FIG. 6, the dummy metal pattern 212 is disposed on the substrate 210 and is aligned to the peripheral slot 213 to offer at least two stiffening edges 212A to enhance the strength of the peripheral slot 213 of the substrate 210. In the present embodiment, the dummy metal pattern 212 and the fingers 211 are formed in a single circuit layer of the substrate 210 as the shadowed area shown in FIG. 4. The circuit layer can be formed on the bottom surface 215 of the substrate 210 to reduce substrate warpage at the peripheral slot 213 of the substrate, to avoid substrate breakage, and to enhance thermal stress resistance of the peripheral slot 213 under temperature cycles. Therefore, damages to the surface and to the sidewalls of the chip 220 can be eliminated.

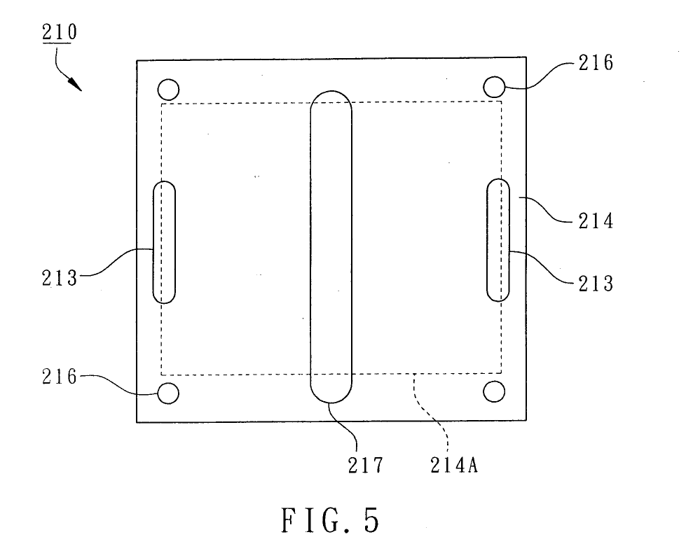

As shown in FIG. 3 and FIG. 5 a die-attaching area 214A is defined on the top surface 214 of the substrate 210 for die attachment. The chip 220 has a footprint on the substrate 210 equal to the die-attaching area 214A. The chip 220 has a plurality of center bonding pads 221 and a plurality of peripheral bonding pads 222. The center bonding pads 221 are normally arranged in single or multiple rows at the center of the active surface of the chip 220. The peripheral bonding pads 222 are located at the peripheries of the active surface of the chip 220 with quantities far less than the one of the center bonding pads 221. As shown in FIG. 8, the peripheral bonding pads 222 are exposed from the two end openings of the peripheral slot 213 and the center bonding pads 221 to the center slot 217 for electrical connections. Furthermore, the active surface of the chip 220 is attached to the substrate 210 by die-attaching materials such as a B-stage printed adhesive or a PI (polyimide) tape.

As shown in FIG. 3, most of the electrical connecting components 230 pass through the center slot 217 to electrically connect the center bonding pads 221 of the chip 220 to the fingers 221 of the substrate 210. At least two of the electrical connecting components 230 pass through two end openings of the peripheral slot 213 to electrically connect the peripheral bonding pads 222 of the chip 220 to the fingers 221 or power/ground fingers 219 of the substrate 210, as shown in FIG. 8. In the present embodiment, the electrical connecting components 230 includes a plurality of bonding wires formed by wire bonding.

The encapsulant 240 encapsulates, the chip 220 and the electrical connecting components 230 and completely fills the peripheral slot 213 and the center slot 217 to provide appropriate protection to prevent electrical short and contaminations. Normally the encapsulant 240 is Epoxy Molding Compound, EMC.

As shown in FIG. 4, to be more specific, the substrate 210 has a plurality of external pads 218 such as round ball pads disposed at the bottom surface 215 of the substrate 210. As shown in FIG. 3, the semiconductor package 200 further comprises a plurality of external terminals 250 disposed on the external pads 218 as electrical connections to an external printed circuit board, not shown in the figure. The external terminals 250 include metal balls, solder paste, contact pads, or contact pins. In the present embodiment, as shown in FIG. 3, the external terminals 250 are solder balls.

As shown in FIG. 3 and FIG. 4, preferably, the substrate 210 further has a plurality of dummy through holes 216 located at the corners of the substrate 210. The encapsulant 240 completely fills the dummy through holes 216 to form a plurality of supporting bumps located at the bump forming areas 241 (as shown in FIG. 4) and extruded from the bottom surface 215. To be more specific, the dummy through holes 216 can locate in a straight line with the peripheral slot 213 and the two end openings of the peripheral slot 213 are oriented towards the dummy through holes 216 to reduce the speed of mold flow in the peripheral slot 213 to eliminate mold flash. Furthermore, the dummy metal pattern 212 is covered by a solder mask to firmly hold the dummy metal pattern 212 in places during package singulation. The external pads 218 can be partially and completely exposed from the solder mask to dispose the external terminals 250.

As shown in FIGS. 3 and 4, the dummy metal pattern 212 is located at the bottom surface 215 of the substrate 210. As shown in FIG. 6, the dummy metal pattern 212 has at least two stiffening edges 212A perpendicular to the opening direction 213A of the peripheral slot 213, where the opening direction 213A is parallel to the two opposing sides of the peripheral slot 213. The dummy metal pattern 212 is copper or other known metals with high hardness. Furthermore, the dummy metal pattern 212 can electrically connect to a power/ground finger 219 adjacent to one end of the peripheral slot 213 for grounding or for signal transmission.

In the present embodiment, the dummy metal pattern 212 includes a strip plate to provide the two stiffening edges 212A where the width of the dummy metal pattern 212 is equal to or greater than 75 μm to effectively increase substrate strengths and to enhance the thermal stress resistance due to temperature fluctuations caused by substrate baking, encapsulant curing, and thermal cycles due to operations. Therefore, the breakage at the peripheral slot 213 and the warpage of the substrate 210 can be avoided and the chip 220 corresponding to the surfaces or to the sidewalls of the peripheral slot 213 will not be damaged, as shown in FIG. 3.

As shown in FIG. 7, before formation of the peripheral slot 213, the dummy metal pattern 212 is extended and covered the designed locations of the peripheral slot 213 then the peripheral slot 213 is formed by routing or by punching so that the dummy metal pattern 212 is extended and aligned to the two opposing sides of the peripheral slot 213. Preferably, the peripheral slot 213 can be a closed slot so that the stiffening edges 212A of the dummy metal pattern 212 are arranged at the two opposing sides of the peripheral slot 213. The peripheral slot 213 can easily be formed in the same process as forming the center slot 217 to reduce the substrate cost.

In the second embodiment of the present invention, another semiconductor package is revealed, primarily comprising a substrate 310, a chip, a plurality of electrical connecting components, and an encapsulant. As shown in FIG. 9, the substrate 310 has a plurality of fingers 311, a dummy metal pattern 312, and at least a peripheral slot 313 penetrating through the substrate 310. The peripheral slot 313 is close to the sides of the substrate 310, each has two end openings replacing a plurality of conventional small peripheral windows to expose the peripheral bonding pads and a dummy passage connecting the end openings. The dummy metal pattern 312 is extended and aligned to two opposing sides of the peripheral slot 313 and is electrically isolated from the fingers 311. All the other components in the second embodiment are almost the same as the ones in the first embodiment. As shown in FIG. 9, in the present embodiment, the dummy metal pattern 312 is located at the top surface 314 of the substrate 310 and has a plurality of stiffening edges 312A perpendicular to the opening direction 313A. The dummy metal pattern 312 further has a plurality of fins 312B to provide at least four or more stiffening edges 312A to increase the warpage resistance of the dummy metal pattern 312. The opening direction 313A is parallel to the two opposing sides of the peripheral slot 313. The fins 312B toward the peripheral slot 313 and arranged as a comb to form the stiffening edges 312A. The dummy metal pattern 312 can provide better thermal stress resistance to protect the peripheral slot 313 from breakage, the substrate 310 from warpage, and the surface or the sidewalls of the chip 320 located adjacent to the small peripheral windows 313 from damages. In the present embodiment, the dummy metal pattern 312 can connect to a signal finger 311 or a power/ground finger 319 and is adjacent to one end of the peripheral slot 313 for the connection of bonding wires.

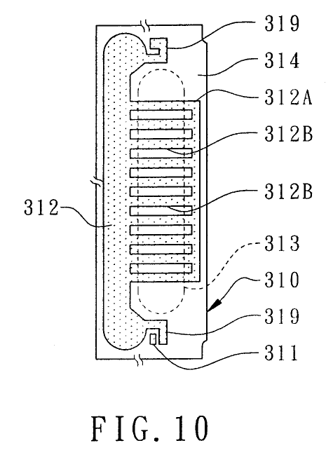

As shown in FIG. 10, before formation of the peripheral slot 313, the plurality of fins 312B of the dummy metal pattern 312 are extended across the designed location of the peripheral slot 313. By routing or by punching the substrate 310 and the dummy metal pattern 312, the fins 312B are aligned to the two opposing sides of the peripheral slot 313 at the same time of the formation of peripheral slot 313 so that the dummy metal pattern 312 can reinforce warpage resistance at the sides of the peripheral slot 313. Additionally, the substrate cost can be reduced.

The above description of embodiments of this invention is intended to be illustrative and not limiting. Other embodiments of this invention will be obvious to those skilled in the art in view of the above disclosure.

What is claimed is:

1. A semiconductor package comprising:
a substrate having a plurality of fingers, a dummy metal pattern, and at least a peripheral slot penetrating through the substrate, wherein the dummy metal pattern is aligned to two opposing sides of the peripheral slot and is electrically isolated from the fingers;
a chip disposed on the substrate and having a plurality of bonding pads;
a plurality of electrical connecting components electrically connecting the bonding pads of the chip to the fingers of the substrate; and
an encapsulant encapsulating the electrical connecting components and completely filling the peripheral slot.

2. The semiconductor package as claimed in claim 1, wherein at least two of the electrical connecting components pass through the peripheral slot.

3. The semiconductor package as claimed in claim 1, wherein the dummy metal pattern has at least two stiffening edges perpendicular to and extending to one of the sides of the peripheral slot.

4. The semiconductor package as claimed in claim 3, wherein the dummy metal pattern includes a strip plate having the stiffening edges.

5. The semiconductor package as claimed in claim 3, wherein the dummy metal pattern includes a plurality of fins toward the peripheral slot and arranged as a comb to form the stiffening edges.

6. The semiconductor package as claimed in claim 1, wherein the dummy metal pattern and the fingers are formed in a single metal layer of the substrate.

7. The semiconductor package as claimed in claim 1, wherein the peripheral slot is a closed slot.

8. The semiconductor package as claimed in claim 1, wherein the substrate further has a plurality of dummy through holes located at a plurality of corners of the substrate, and wherein the encapsulant further has a plurality of supporting bumps extruded from the bottom surface of the substrate and completely filled the dummy through holes.

9. The semiconductor package as claimed in claim 1, wherein the substrate further has a solder mask covering the dummy metal pattern.

10. The semiconductor package as claimed in claim 1, wherein the substrate further has a connecting finger adjacent to one end of the peripheral slot and connected with the dummy metal pattern.

11. The semiconductor package as claimed in claim 1, wherein the substrate further has a central slot parallel to the peripheral slot for passing through the electrical connecting components

12. A substrate for a semiconductor package comprising a plurality of fingers, a dummy metal pattern, and at least a peripheral slot penetrating through the substrate, wherein the dummy metal pattern is aligned to two opposing sides of the peripheral slot and is electrically isolated from the fingers.

13. The substrate as claimed in claim 12, wherein the dummy metal pattern has at least two stiffening edges perpendicular to and extending to one of the sides of the peripheral slot.

14. The substrate as claimed in claim 13, wherein the dummy metal pattern includes a strip plate having the stiffening edges.

15. The substrate as claimed in claim 12, wherein the dummy metal pattern includes a plurality of fins toward the peripheral slot and arranged as a comb to form the stiffening edges.

16. The substrate as claimed in claim 12, wherein the dummy metal pattern and the fingers are formed in a single metal layer of the substrate.

17. The substrate as claimed in claim 12, wherein the peripheral slot is a closed slot.

18. The substrate as claimed in claim 12, further comprising a plurality of dummy through holes located at a plurality of corners thereof.

19. The substrate as claimed in claim 12, further comprising a solder mask covering the dummy metal pattern.

20. The substrate as claimed in claim 12, further comprising a connecting finger adjacent to one end of the peripheral slot and connected with the dummy metal pattern.

21. The substrate as claimed in claim 12, further comprising a central slot parallel to the peripheral slot.
